(19) United States
(12) Patent Application Publication
(10) Pub. No.: US 2024/0329095 A1
(43) Pub. Date: Oct. 3, 2024

(54) MEASURING METHOD AND SINGLE-TORUS LOOP OHMMETER WITH DC LEAKAGE FLUX COMPENSATION

(71) Applicant: CHAUVIN ARNOUX, Asnieres-Sur-Seine (FR)

(72) Inventors: Jerome ADAM, Asnieres-Sur-Seine (FR); Philippe LEGROS, Asnieres-Sur-Seine (FR)

(21) Appl. No.: 18/620,137

(22) Filed: Mar. 28, 2024

(30) Foreign Application Priority Data
Mar. 29, 2023 (FR) 23 03022

(51) Int. Cl. G01R 15/18; G01R 27/18; G01R 31/52

(52) U.S. Cl. CPC G01R 15/185; G01R 27/18; G01R 31/52

(57) ABSTRACT

A single-torus ohmmeter for measuring a loop impedance Zx, includes a single transformer having a primary winding of Np coils and a secondary winding of a single coil forming a measurement loop of impedance Zx, in which, to compensate for a stray induction produced by a DC leakage current circulating in the measurement loop without canceling a measurement current Ip generating an alternating induction of constant average value for the measurement of the loop impedance Zx, the transformer includes a second secondary winding of Na coils whose output voltage Ub is delivered to a processing module providing a voltage intended to be added to an alternating measurement voltage Vp in an adder delivering the current to be injected into the primary winding after passage through a voltage-current converter supplying current to the primary winding via a shunt resistance.

### TECHNICAL FIELD

The present invention relates to the field of the control of electrical installations and more particularly concerns the measurement of ground resistances by means of loop ohmmeters.

### BACKGROUND

Loop ohmmeters are apparatuses intended to check the conformity of the ground connections of electrical installations or buildings such as illustrated in FIG. 1. They are particularly suitable when the electrical installation has multiple groundings in parallel forming several successive ground loops because the measurement does not require planting auxiliary stakes into the ground or opening a ground connection (ground strap for example) to isolate the electrical installation.

Conventionally, loop ohmmeters involve the use of two transformers magnetically isolated from each other and enclosing the ground connection conductor, one to inject a voltage by induction and the other to measure the current circulating in the loop. The impedance of the ground connection is then deduced from the ratio between this voltage and the measured current.

However, and as shown in FIG. 2, it is known from patent EP1 566 644 B1 filed in the name of the Applicant a single-torus loop ohmmeter which makes it possible to dispense with the current transformer and the magnetic isolation between the two transformers using only a single transformer consisting of a torus with a primary winding Np, used simultaneously for the injection of the voltage and the measurement of the current circulating in the ground loop, and a single-coil secondary winding Ns formed by the ground connection conductor and whose loop impedance Zx is to be measured. The application of a setpoint voltage Vp across the primary of the transformer circulates in this primary a measurement current Ip which induces, in the enclosed conductor forming the secondary, the secondary voltage Vs generating the secondary current Is=Vs/Zx circulating in the loop, m being the ratio of the numbers of turns of the secondary winding Ns and of the primary winding Np, i.e. m=Ns/Np.

Given that the voltage applied across the primary Vp is a known quantity, if the transformer were a perfect transformer, it would be sufficient to measure the primary current Ip to know the impedance Zx. But, in reality, the transformer is not perfect and has magnetic flux losses, iron and copper losses and finite magnetic circuit permeability.

Also, FIG. 3 illustrates the equivalent electrical diagram of the actual transformer brought back to the primary on which, Rf represents the resistance equivalent to the iron losses of the transformer, Lu represents the magnetizing inductance of the transformer, that is to say the image of the non-infinite permeability of the magnetic circuit, If and Iμ represent the components of the magnetizing current of the transformer, Rp represents the resistance of the primary winding, that is to say the image of the copper losses, lp represents the leakage inductance of the primary, that is to say the image of the magnetic flux losses, Rs represents the resistance of the secondary winding, Is represents the leakage inductance of the secondary and Ep represents the actual voltage generating the magnetic flux of the transformer.

This equivalent diagram can be simplified given that the winding Ns being constituted by the loop whose impedance Zx is to be measured, it follows that Ns=1 and Is becomes negligible and can be considered as equal to zero, just as Rs, and that the value of Rp is negligible compared to ZxNp² hence Rp≈0.

The equivalent diagram is therefore reduced to the simplified form illustrated in FIG. 4, which allows writing: Ip/Vp=1/Z=1/Rf+1/jLμω+1/ZxNp²

Where ω=2πf, f being the frequency of the setpoint voltage Vp.

The loop impedance measuring method described above therefore requires permanent knowledge of the values of Rf and Lμ to determine Zx. These two values are obtained at no load (open loop) before the installation of the torus of the transformer around the loop whose impedance Zx is to be measured.

However, these values change as a function of the induction level in the torus which depends on the presence of the AC and DC stray currents circulating in the measurement loop and which must therefore be compensated so that the values remain exploitable during the measurement phase and guarantee the desired measurement accuracy over the desired measurement range.

### SUMMARY

The main aim of the present invention is to reduce the influence of the induction in the torus (and mainly on the iron losses whose Rf is the electrical model) due to the presence of stray DC direct current in the measurement loop.

This aim is achieved by a method for measuring a loop impedance Zx in a single-torus ohmmeter including a single transformer having a primary winding of Np coils and a secondary winding of a single coil forming a measurement loop of impedance Zx, characterized in that, to compensate for a DC leakage current circulating in the measurement loop without canceling a measurement current Ip generating an alternating induction of constant average value for the measurement of the loop impedance Zx, said measurement current Ip is added to a constant current opposite and proportional to the stray induction produced by the DC leakage current, to be re-injected into the primary winding.

This stray induction can be measured by different methods such as a Hall effect or fluxgate sensor or a Rogowski loop, but according to one advantageous embodiment, the measurement of the stray induction is derived from an output voltage Ub delivered across a second secondary winding of Na coils of the single transformer and first integrated then successively subject to a comparison with a determined threshold and to a low-pass filtering.

Thus, by measuring, by any means whatsoever and preferably by means of a second secondary winding, a quantity whose amplitude is correlated to a direct component of the induction resulting from a DC leakage current, and by compensating for the associated magnetic fields by injecting a DC current into the primary, the influence of this DC leakage current circulating in the measurement loop on the iron losses is reduced.

Advantageously, the comparison consists in determining the duration during which the output voltage Ub is positive and the duration during which it is negative.

The invention also relates to a single-torus loop ohmmeter implementing the aforementioned method.

According to the envisaged embodiment, the module for processing the output voltage of the second secondary winding can consist of an integrator followed by a comparator with a determined threshold and by a low-pass filter, the voltage-current converter and the value of the shunt resistance being chosen so that the number of ampere-turns provided by the primary winding to a magnetic core of the single transformer is equal to the number of ampere-turns provided to this magnetic core by the single-coil secondary winding, or the module for processing the output voltage of the second secondary winding can consist of an integrator followed by a comparator with a determined threshold and by a low-pass filter whose output voltage is corrected in a digital correction module.

Advantageously, the digital correction module consists of a microcontroller preceded by an analog-to-digital converter and followed by a digital-to-analog converter.

Preferably, the comparator is configured to determine the duration during which the output voltage Ub is positive and the duration during which it is negative.

Advantageously, the ratio between the number of coils Np of the primary winding and the number of coils Na of the second secondary winding is equal to one.

Preferably, the transformer is made in the form of a non-opening magnetic sensor left permanently on a ground connection conductor and the loop impedance Zx is transmitted periodically to a remote server via at least one communication network.

### BRIEF DESCRIPTION OF THE DRAWINGS

Other characteristics and advantages of the present invention will emerge from the description given below, with reference to the appended drawings which illustrate one exemplary embodiment devoid of any limitation and in which:

FIG. 1 shows a set of electrical lines including ground contacts connecting various buildings together,

FIG. 2 schematically shows a single-torus loop ohmmeter,

FIG. 3 shows the equivalent electrical diagram of an actual transformer brought back to the primary,

FIG. 4 shows the simplified diagram of the transformer of FIG. 3,

FIG. 5 shows two curves of the voltage across the second secondary winding of the transformer,

FIG. 6 is a block diagram of a single-torus loop ohmmeter with DC leakage flux compensation according to the invention, and

FIG. 7 is a block diagram of a single-torus loop ohmmeter with DC leakage flux compensation in the case of an only analog processing.

### DETAILED DESCRIPTION OF THE INVENTION

The principle of the invention is based on a measurement of the induction using a second secondary winding to compensate for its influence on Rf and Lu. By using this second secondary winding whose output voltage is the derivative of the magnetic flux as an indicator of the DC flux, a proportional current is re-injected into the primary winding to compensate for this disturbing DC flux created by the current to be measured circulating in the measurement loop, without having to interrupt the measurement.

However, as shown in FIG. 5, the passage of a DC current through a torus (the ferromagnetic element of the transformer) of high permeability polarizes it and distorts the hysteresis cycle. As a result, a sinusoidal signal circulating in a primary winding is not perfectly reproduced in a secondary winding, particularly the duration during which the signal of the secondary winding is positive is different from the duration during which it is negative. Thus, in the figure showing the signal observed across this secondary winding, the dotted curve corresponds to the case where the DC leakage current is zero and shows a perfectly sinusoidal voltage of the secondary winding, and the solid line curve corresponds to the presence of a DC leakage current through the torus and shows a voltage of the secondary winding distorted in amplitude and not passing through the central point of the reading. Particularly, the duration of the positive part of the voltage is shorter than the duration of its negative part.

Based on this observation, the invention proposes to compare the duration of the positive alternation with the duration of the negative alternation of the signal taken from the second secondary winding to ensure a compensation for the stray direct current circulating in the measurement loop (hereinafter DC leakage current).

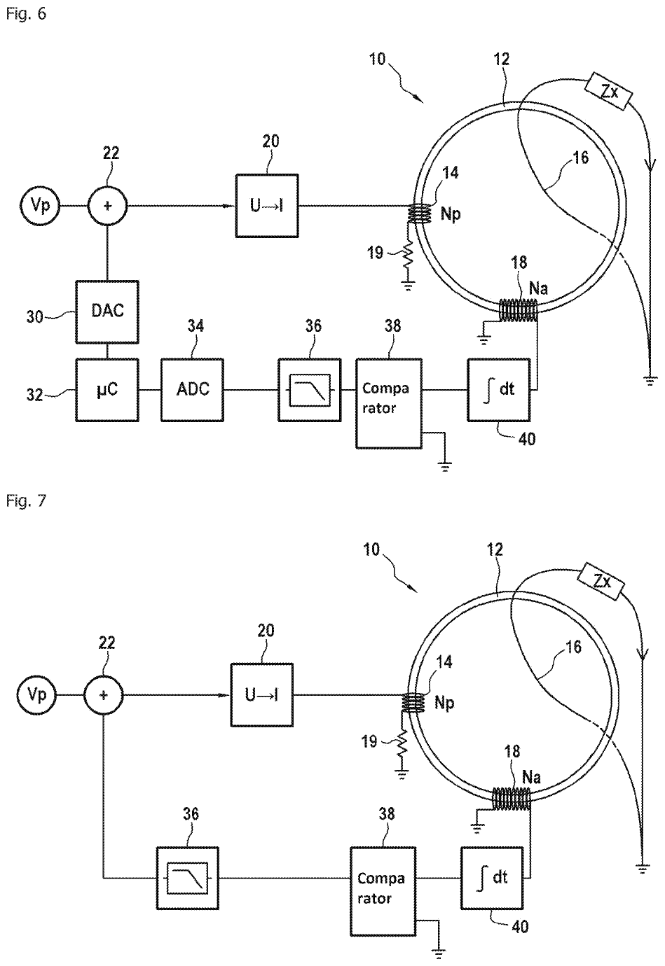

FIG. 6 illustrates a first block diagram of this compensation performed in the single-torus loop ohmmeter of the invention.

The transformer 10 is illustrated by its torus (the magnetic core 12), the primary winding 14 of Np coils, the single-coil Ns secondary winding 16 formed by the measurement loop of the impedance Zx and the second secondary winding 18 of Na coils. Preferably, the ratio between the numbers of coils at the primary winding Np and at the second secondary winding Na is equal to one without this ratio being limiting (this ratio can be greater or less than 1). The current injected into the primary winding 14 and whose amplitude is set by a shunt resistance 19 is derived from a voltage-current converter 20, typically with an operational amplifier, receiving the output of an adder 22 intended to add a compensation signal (intended to create an alternating induction of constant average value in the torus) to the measurement signal and therefore receiving on the one hand the alternating measurement voltage Vp corresponding to the useful voltage for measuring Zx and on the other hand a voltage Ucomp which corresponds to the servo-control set up to compensate for the DC leakage current, and which is taken at the output of a digital-to-analog converter (DAC 30) driven from a microcontroller 32 preceded by an analog-to-digital converter (ADC 34) whose input is taken at the output of a low-pass filter 36 itself preceded by a comparator 38 whose input is connected to an integrator 40 necessary to obtain a signal representing the induction in the torus, that is to say to find a constant current opposite to the DC leakage current and representing the magnetic field derived from this DC leakage current and taken across the second secondary winding 18. The comparator with a determined threshold makes it possible to compare the duration during which the output voltage Ub is positive and the duration during which it is negative, that is to say the periods where the induction in the magnetic core (the torus) is greater than 0 and the one where it is less than 0.

The set of the DAC 30, microcontroller 32 and ADC 34 forms a digital correction module which, associated with the integrator 40, comparator 38 and low-pass filter 36, constitutes a module for processing the output voltage Ub.

The microcontroller 32 records and stores one (or advantageously several values) of the integrated measurement (monotonic value and not directly proportional to the DC induction) of the output of the comparator in the absence of leakage current: for an open loop, and advantageously for one or several closed loops on a known impedance. These values make it possible to define a servo-control setpoint which modifies the current generated so that the measurement of the average of the values taken converges towards the setpoint.

FIG. 7 illustrates a second block diagram of the compensation performed in the single-torus loop ohmmeter in the case of using an only analog processing instead of a mixed analog and digital processing.

In this configuration, the adder directly receives the analog compensation current derived from the low-pass filter and the voltage-current converter 20 as well as the value of the shunt resistance 19 are then chosen such that the number of ampere-turns provided by the winding 14 to the magnetic core 12 is equal to the number of ampere-turns provided to this magnetic core by the single winding 16. Thus, by ensuring that the directions of circulation of the current in the windings 14 and 16 are opposite to each other, the direct magnetic flux coupled to the magnetic core 12 by the single winding 16 is canceled by the direct magnetic flux coupled to the magnetic core 12 by the winding 14.

Left permanently on a ground connection conductor, that is to say with a transformer forming a non-opening magnetic sensor, the loop ohmmeter according to the invention can permanently monitor the loop impedance Zx, and therefore the ground impedance synonymous with quality of protection at the point of installation of this sensor.

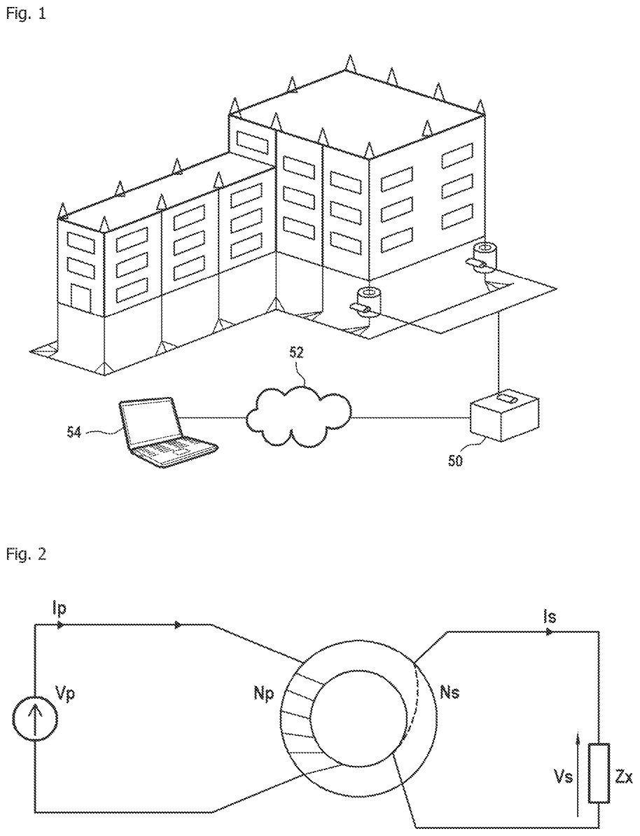

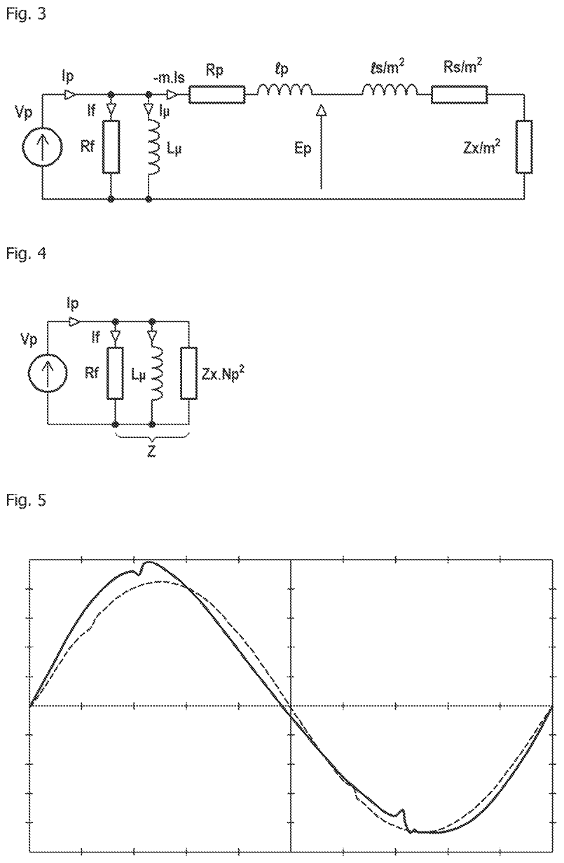

As shown in FIG. 1, it can include its own means of communication in connection via a communication network, advantageously a wireless communication network (of the 3G-5G or Wi-Fi type in particular) or a wired communication network (Ethernet in particular) with the corresponding means of communication of a local measurement box 50 to regularly transmit its impedance measurements to a remote server 52 via the Internet network 54 for example, thus avoiding the need for an operator to travel to ensure the control of the impedance Zx.

With the invention, the DC leakage current is compensated without canceling the measurement current injected for the measurement of the loop impedance Zx. Indeed, the measurement current Ip intended to be injected on the primary winding Np must not be impacted by the servo-control of the DC leakage current, hence the presence of the low-pass filtering in the compensation signal of the DC leakage current so that this compensation does not cancel the measurement current.

1. A method for measuring a loop impedance Zx in a single-torus ohmmeter including a single transformer having a primary winding of Np coils and a secondary winding of a single coil forming a measurement loop of impedance Zx, wherein, to compensate for a stray induction produced by a DC leakage current circulating in the measurement loop without canceling a measurement current Ip generating an alternating induction of constant average value for the measurement of the loop impedance Zx, said measurement current Ip is added to a constant current opposite and proportional to the stray induction produced by the DC leakage current, to be re-injected into the primary winding.

2. The method for measuring a loop impedance Zx according to claim 1, wherein the measurement of the stray induction is derived from an output voltage Ub delivered across a second secondary winding of Na coils of the single transformer and first integrated then successively subject to a comparison with a determined threshold and to a low-pass filtering.

3. The method for measuring a loop impedance Zx according to claim 1, wherein the comparison consists in determining the duration during which the output voltage Ub is positive and the duration during which it is negative.

4. A single-torus ohmmeter for measuring a loop impedance Zx, including a single transformer having a primary winding of Np coils and a secondary winding of a single coil forming a measurement loop of impedance Zx, characterized in that, to compensate for a stray induction produced by a DC leakage current circulating in the measurement loop without canceling a measurement current Ip generating an alternating induction of constant average value for the measurement of the loop impedance Zx, the transformer includes a second secondary winding of Na coils whose output voltage Ub is delivered to a processing module providing a voltage intended to be added to an alternating measurement voltage Vp in an adder delivering the current to be injected into the primary winding after passage through a voltage-current converter supplying current to the primary winding via a shunt resistance.

5. The single-torus ohmmeter according to claim 4, wherein the module for processing the output voltage of the second secondary winding consists of an integrator followed by a comparator with a determined threshold and by a low-pass filter, the voltage-current converter and the value of the shunt resistance being chosen so that the number of ampere-turns provided by the primary winding to a magnetic core of the single transformer is equal to the number of ampere-turns provided to this magnetic core by the single-coil secondary winding.

6. The single-torus ohmmeter according to claim 4, wherein the module for processing the output voltage of the second secondary winding consists of an integrator followed by a comparator with a determined threshold and by a low-pass filter whose output voltage is corrected in a digital correction module.

7. The single-torus ohmmeter according to claim 6, wherein the digital correction module consists of a microcontroller preceded by an analog-to-digital converter and followed by a digital-to-analog converter.

8. The single-torus ohmmeter according to claim 5, wherein the comparator is configured to determine the duration during which the output voltage Ub is positive and the duration during which it is negative.

9. The single-torus ohmmeter according to claim 4, wherein the ratio between the number of coils Np of the primary winding and the number of coils Na of the second secondary winding is equal to one.

10. The single-torus ohmmeter according to claim 4, wherein the transformer is made in the form of a non-opening magnetic sensor left permanently on a ground connection conductor and the loop impedance Zx is transmitted periodically to a remote server via at least one communication network.
